(19) United States
(12) Patent Application Publication
(10) Pub. No.: US 2011/0089994 A1
(43) Pub. Date: Apr. 21, 2011

(54) Threshold Voltage Modification Via Bulk Voltage Generator

(75) Inventors: Martin Clara, Villach (AT); Daniel Gruber, St. Andra (AT); Wolfgang Klatzer, Mittertrixen (AT)

(73) Assignee: Infineon Technologies AG, Neubiberg (DE)

(21) Appl. No.: 12/580,588

(22) Filed: Oct. 16, 2009

(51) Int. Cl. H03K 3/01

(52) U.S. Cl. 327/534

(57) ABSTRACT

The present disclosure relates to threshold voltage modification via a voltage generator connected to bulk nodes of transistors.

### BACKGROUND

Various types of communication and control devices include digital to analog (D/A) converters to convert a digital signal including binary coded information to an analog signal, such as current or voltage. For example, wireless and wireline communication devices may include a current steering D/A converter in a transmitter section of a transceiver to convert a digital input signal to an analog output signal to be transmitted via a particular communication device. A current steering D/A converter may include a number of cells with each cell including a current source and a switch to direct current from the current source to one of a plurality of outputs of the cell. In some implementations, the current switch may include a pair of transistors. When the current steering D/A converter receives a digital input signal, current from the current source of each cell is directed to a particular output based on the code of the digital input signal.

The linear output voltage range of a current steering D/A converter is given by the output voltage range for which activated switch transistors of the cells in a current steering D/A converter are kept in saturation. Specifically, the linear output voltage range of current steering D/A converters may be limited by the threshold voltage of the activated switch transistors. As technologies utilized to manufacture the transistors have changed, the threshold voltage of the transistors has decreased in advanced CMOS processes. Consequently, as the threshold voltage of the activated transistors decreases, further amplification of the output voltage is needed in order to efficiently utilize the output voltage in other nodes of a communication device, which results in higher power consumption.

In some instances, the threshold voltage of switch transistors of the current steering D/A converter may be increased by changing the channel width to channel length ratio of the transistors, but the resulting threshold voltage increase is not always sufficient. Further, in other instances, the bulk region of each of the switch transistors of the current steering D/A converter is connected to the supply voltage. Thus, the threshold voltages of the transistors are limited based on the supply voltage. The threshold voltage of the transistors of the current steering D/A converter may be increased by connecting the bulk region of each switch transistor to an additional supply voltage. However, connecting the bulk region of each of the transistors of the current steering D/A converter to an additional supply voltage increases the pin count and the system complexity, because the additional supply voltage may not be available on-chip and must therefore be generated externally.

In addition, the output voltage range of a current steering D/A converter may be limited by the activation voltage actually applied to turn on the transistors of the current steering D/A converter. Thus, the output voltage range may be increased by increasing the activation voltage applied to the transistors of the current steering D/A converter. In some implementations, the activation voltage of the activated transistors is increased via a level-shifter. The use of a level-shifter to increase the activation voltage of transistors of the current steering D/A converter generally results in an increase in power consumption. Another possibility is to provide the activation voltage via an additional supply voltage, but, again, this will result in an increased pin count and system complexity.

### BRIEF DESCRIPTION OF THE DRAWINGS

The detailed description is described with reference to the accompanying figures. In the figures, the left most digit(s) of a reference number identifies the figure in which the reference number first appears. The use of the same reference numbers in different figures indicates similar or identical items.

FIG. 1 shows an exemplary system to modify a threshold voltage of transistors of a switched current source via a bulk-connected voltage generator.

FIG. 2 shows an exemplary current steering digital to analog converter with a voltage generator connected to the respective bulk regions of transistors transistor switches of the digital to analog converter.

FIG. 3 shows an exemplary system including a wireless communication device comprising a voltage generator connected to a bulk region of one or more transistors of a digital to analog converter of a transceiver of the wireless communication device.

FIG. 4 shows a schematic circuit diagram of an architecture including a digital to analog converter circuit connected to an on-chip voltage generator that is connected to a bulk region of PMOS transistors of transistor switches of the digital to analog converter circuit.

FIG. 5 shows a schematic circuit diagram of an architecture including a digital to analog converter circuit connected to an on-chip voltage generator that is connected to a bulk region of NMOS transistors of transistor switches of the digital to analog converter.

FIG. 6 shows a schematic circuit diagram of an architecture to regulate a charge pump of a voltage generator connected to a bulk region of transistor switches of current steering digital to analog converter circuitry.

FIG. 7 shows a flowchart of a method to modify a threshold voltage of transistors of transistor switches of a digital to analog converter via a bulk connected voltage generator.

### DETAILED DESCRIPTION

The disclosure is directed to threshold voltage modification via a bulk-connected voltage generator. In one implementation, a device includes a current source connected to a supply voltage. The current source is connected to a first transistor and a second transistor and the first and second transistors are connected to each other. The device also includes a voltage generator that is connected to a bulk region of the first transistor and a bulk region of the second transistor. In some implementations, the current source and the first and second transistors are included in current steering digital to analog (D/A) conversion circuitry of a communication device. By connecting the bulk region of the first transistor and the bulk region of the second transistor to an on-chip voltage generator, the threshold voltage of the first and second transistors may be increased. In this way, the linear range of the output voltage of the D/A conversion circuitry increases and the power consumption of a communication device including the D/A conversion circuitry decreases due to a reduced need to amplify the output voltage in other nodes of the communication device.

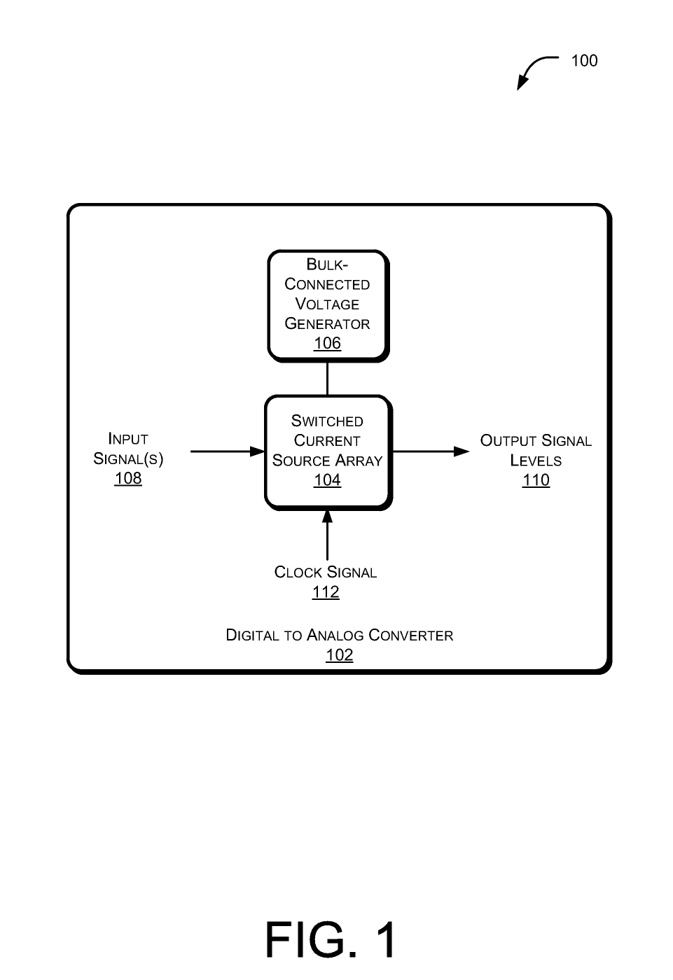

FIG. 1 shows an exemplary system 100 which is able to synthesize analog signals from at least one digital input signal. To that aim, the system 100 includes at least one digital to analog (D/A) converter 102. In some implementations, the D/A converter 102 is included in a transmitter section of a communication device.

The D/A-converter 102 includes a switched current source array 104. The switched current source array 104 includes a number of current sources and a number of switches, where each current source is connected to a respective switch. Additionally, each switch is comprised of a pair of transistors. The switches of the switched current source array 104 operate to steer the current provided by each respective current source to one of a plurality of output nodes. In one illustration, one switch transistor of each pair of transistors may be activated at a given time to steer current from the current source to an output node connected to the activated switch transistor. The D/A-converter 102 also includes a bulk-connected voltage generator 106 that is connected to the bulk region of at least one of the switch transistors of each transistor pair of the switched current source array 104. The bulk-connected voltage generator 106 may increase the voltage of the bulk region of the switch transistors, such that the linear output voltage range increases, thus requiring less amplification of analog signals. This generally results in decreased power consumption, such as decreased power consumption in a transmitter section of a communication device.

The switched current source array 104 receives one or more input signals 108, such as a digital signal that includes a code of binary numbers. The switched current source array 104 produces one or more analog output signal levels 110 corresponding to the one or more input signals 108. The D/A converter 102 also receives a clock signal 112. The clock signal 112 may be produced by a clock generator, a phase lock loop circuit, or another clock source.

In a particular implementation, the switched current source 104 receives a digital input signal and produces one or more analog output signal levels corresponding to the digital input signal. For example, the value of each bit of the digital input signal may be represented by current provided by a respective current source and the current from each respective current source may be steered to a particular output node based on the value of the corresponding bit of the digital input signal. To illustrate, a switch of the switched current source array 104 may steer current from a particular current source to a first output node when the value of a corresponding bit of the digital signal is a logical one and to a second output node when the value of the corresponding bit of the digital signal is a logical zero.

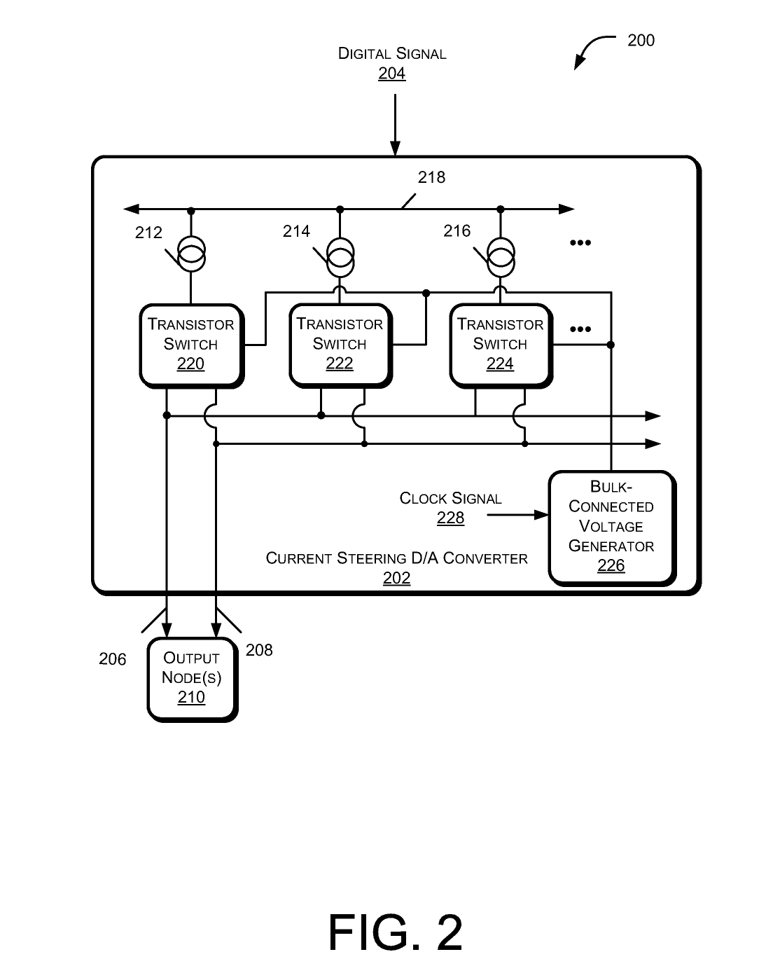

FIG. 2 shows an exemplary system 200 including a current steering digital to analog (D/A) converter 202 with a voltage generator connected to the respective bulk regions of transistors of the digital to analog converter 202. The current steering D/A converter 202 receives a digital signal 204 and provides a first output signal 206 and a second output signal 208 to one or more output nodes 210. For example, the one or more output nodes 210 may include one or more impedance devices, one or more filters, one or more mixers, one or more amplifier devices, or a combination thereof. The one or more output nodes 210 may perform specified operations in response to receiving the first output signal 206, the second output signal 208, or a combination thereof, such as producing an analog output voltage. In some implementations, the current steering D/A converter 202 is included in a transmitter section of a communication device.

The current steering D/A converter 202 includes a number of current sources, such as current sources 212-216. The current sources 212-216 may be approximately identical current sources, such as current sources of a thermometer coded D/A converter, binary weighted current sources, or a combination thereof. Each of the current sources 212-216 is connected to a supply voltage via a path 218, such as a positive supply voltage or a negative supply voltage. In addition, each of the current sources 212-216 is connected to a respective transistor switch 220-224. Each of the transistor switches 220-224 may include a pair of transistors, such as negative channel metal-oxide semiconductor (NMOS) transistors, positive channel metal-oxide semiconductor (PMOS) transistors, or a combination thereof. Further, the current steering D/A converter 206 includes a bulk-connected voltage generator 226. The bulk-connected voltage generator 226 is connected to a bulk region of at least one transistor of each transistor switch 220-224. The bulk-connected voltage generator 226 produces a particular voltage at the bulk region of each transistor connected to the bulk-connected voltage generator 226. In some implementations, the bulk-connected voltage generator 226 is connected to the supply voltage via the path 218 and the bulk-connected voltage generator 226 utilizes the supply voltage to produce a voltage in the bulk regions of the transistors of the transistor switches 220-224 that is different from the supply voltage. For example, the bulk-connected voltage generator 226 may include a voltage doubler circuit. The bulk-connected voltage generator 226 may also include a DC/DC converter. Further, the bulk-connected voltage generator 226 receives a clock signal 228.

In an illustrative implementation, each bit of the digital signal 204 corresponds to a particular current source 212-216. For example, the value of a first bit of the digital signal 204 is represented by current from the first current source 212 and the value of a second bit of the digital signal 204 is represented by current from the second current source 214. In this example, current from the first current source 212 is steered by the transistor switch 220 to contribute to one of the output signals 206, 208 based on the value of the first bit of the digital signal 204. Continuing with this example, current from the second current source 214 is steered by the transistor switch 222 to contribute to one of the output signals 206, 208 based on the value of the second bit of the digital signal 204. To illustrate, when the value of the first and/or second bit of the digital signal 204 is a logical one, the current from the current source 212 and/or current from the current source 214 may be steered by the transistor switch 220 and/or the transistor switch 222 to contribute to the first output signal 206. Additionally, when the value of the first and/or second bit of the digital signal 204 is a logical zero, the current from the current source 212 and/or current from the current source 214 may be steered by the transistor switch 220 and/or the transistor switch 222 to contribute to the second output signal 208. In some implementations, the current from the current sources 212-216 may be summed before providing the first output signal 206 and/or the second output signal 208 to the one or more output nodes 210. An analog output voltage may be produced that represents the digital signal 204 by sending the first output signal 206 and/or the second output signal 208 through one or more impedance devices of the output nodes 210. Since the analog output voltage depends on the threshold voltage of the transistor switches 220-224, producing a higher threshold voltage via the on-chip bulk-connected voltage generator 226 leads to a larger linear output voltage range of the D/A-converter, thus reducing the need for further amplification of the analog output voltage. In a particular implementation, the need to further amplify the analog output voltage in other nodes of a transmitter of a communication device is reduced. Therefore the power consumption of a device, such as a transmitter, including the current steering D/A converter 202 is reduced.

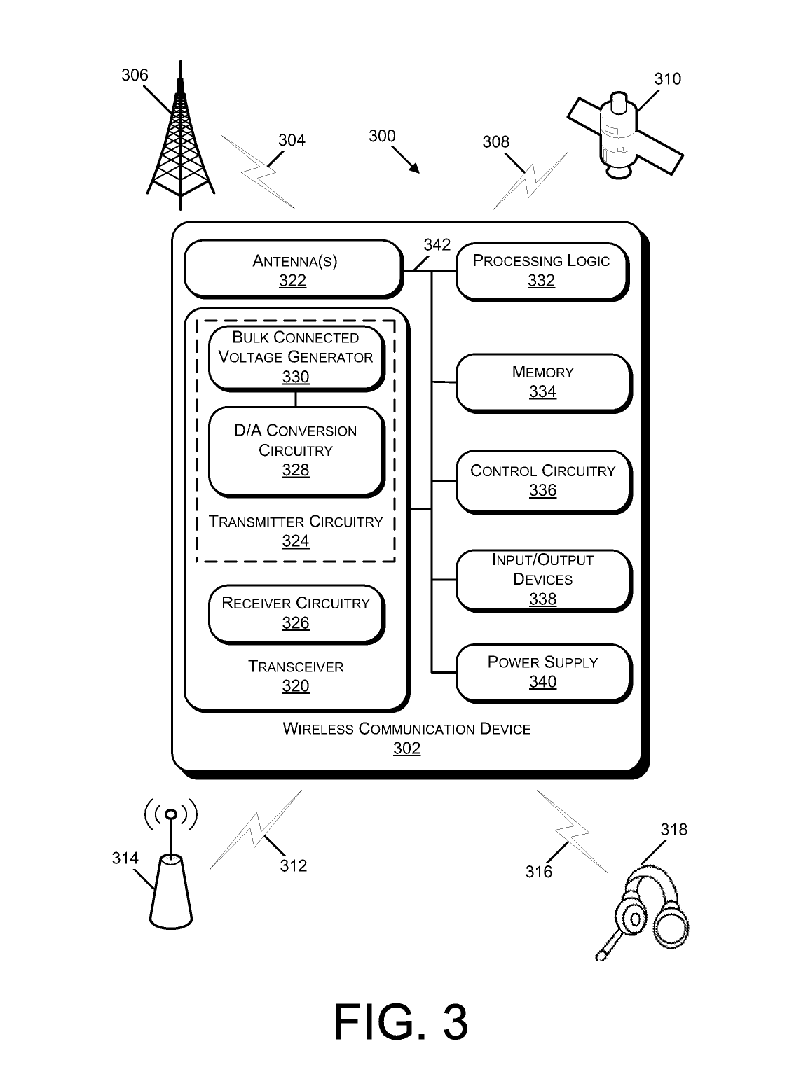

FIG. 3 shows an exemplary system 300 including a wireless communication device 302 comprising a voltage generator connected to a bulk region of one or more transistors of a digital to analog converter of the wireless communication device 302. The wireless communication device 302 is configured to transmit wireless signals to, and receive wireless signals from one or more external devices. The wireless signals may include voice traffic, data, control information, or any combination thereof. The wireless communication device 302 may be implemented in any number of ways, including as a smart phone, a hand-held communication device (e.g., a personal digital assistant (PDA)), a mobile telephone, a media playing device, a portable gaming device, a personal computer, a laptop computer, another suitable wireless communication device, or any combination thereof.

In one implementation, the wireless communication device 302 may transmit and/or receive wireless signals 304 via a base station 306. The base station 306 may be included in a wide area wireless communication network, such as a global system for mobile communications (GSM) network, a UMTS network, a CDMA network, a high speed packet access (HSPA) network, a general packet radio service (GPRS) network, an enhanced data rates for GSM evolution (EDGE) network, a worldwide interoperability for microwave access (WiMAX) network, a time division multiple access (TDMA) network, a frequency division multiple access (FDMA) network, a long term evolution (LTE) network, a WiMedia ultra wideband (UWB) network, or any combination thereof.

In another implementation, the wireless communication device 302 may transmit and/or receive wireless signals 308 via a communication satellite 310. Further, the wireless communication device 302 may transmit and/or receive wireless signals 312 via a wireless access point 314. The wireless access point 314 may be included in a wide area wireless network or a wireless local area network, such as a Bluetooth network or an Institute of Electrical and Electronics Engineers (IEEE) 802.11 protocol network. Additionally, the wireless communication device 302 may transmit and/or receive wireless signals 316 via a headset 318, such as a Bluetooth headset.

In a particular implementation, the wireless communication device 302 includes a transceiver 320 to transmit and receive signals via one or more antennas 322. In particular, the transceiver 320 is configured to process signals to be transmitted and to process signals received via one or more wireless communication technologies. The one or more antennas 322 may be placed in various locations of the wireless communication device 302, such as a bottom portion or a top portion of the wireless communication device 302.

The transceiver 320 includes transmitter circuitry 324 to transmit signals via the one or more antennas 322 and receiver circuitry 326 to process signals received via the one or more antennas 322. The transmitter circuitry 324 includes digital to analog (D/A) conversion circuitry 328, such as the current steering D/A converter 202 of FIG. 2 or the D/A converter 102 of FIG. 1, and a bulk connected voltage generator 330. The transmitter circuitry 324 may also include one or more switches, one or more filters, one or more power amplifiers, one or more mixers, or a combination thereof. Further, the receiver circuitry 326 may include one or more filters, one or more low noise amplifiers, one or more mixers, or a combination thereof.

In an illustrative implementation, the transceiver 320 receives a digital signal that includes information that is to be transmitted via the one or more antennas 322 to one or more of the external devices 306, 310, 314, 318. The digital signal may represent voice information and/or data to be transmitted via the one or more antennas 322. For example, the digital signal may represent voice information from a phone call conducted utilizing the wireless communication device 302, a request for information from a remote source, such as information associated with a web page, a text message, an email, a picture message, a video message, or a combination thereof. The digital signal is converted to an analog output signal via the D/A conversion circuitry 328, such as via a current steering D/A converter, and the analog output signal may then be provided to the one or more antennas 322. The bulk-connected voltage generator 330 produces a voltage in the bulk regions of transistors included in the D/A conversion circuitry 328. Thus, the bulk-connected voltage generator 330 increases the threshold voltage of the transistors of the D/A conversion circuitry 328 and, consequently, increases the strength of the analog output signal. By increasing the strength of the analog output signal, the need for further amplification of the analog output signal in the wireless communication device 302 is reduced, which reduces power consumption of the wireless communication device 302.

The wireless communication device 302 also includes additional components, such as processing logic 332 and memory 334. The processing logic 332 may include one or more processors and the memory 334 is accessible to the processing logic 332. The memory 334 may include read-only memory (ROM), random access memory (RAM), flash memory, a hard disk, or any combination thereof. Additionally, the memory 334 may store one or more applications configured to transmit and/or receive wireless signals. For example, the memory 334 may store an application configured to send and receive wireless signals related to telephone calls, such as voice traffic or control information. In another example, the memory 334 may store an application configured to request and receive website data, an application configured to transmit and receive text messages, an application configured to transmit and receive picture messages, an application configured to transmit and receive video messages, or any combination thereof. The applications stored in the memory 334 may include software instructions, hardware, or any combination thereof.

Additionally, the wireless communication device 302 includes control circuitry 336. The control circuitry 336 provides control signals to the components of the wireless communication device 302, such as the transceiver 320. In a particular implementation, the control circuitry 336 provides control signals to the D/A conversion circuitry 328 to facilitate the conversion of information included in a digital signal to one or more analog output signals. For example, the control circuitry 336 may provide control signals to driver logic of the D/A conversion circuitry 328. The driver logic of the D/A conversion circuitry 328 is configured to turn on or off transistors of the D/A conversion circuitry 328 to steer current to produce particular output signals based on the information of the digital signal.

Further, the wireless communication device 302 includes one or more input/output devices 338. In an illustrative embodiment, the input/output devices 338 may include a microphone, a speaker, a touchpad display, a cursor control device, such as a mouse, a keypad, or any combination thereof. Additionally, the wireless communication device 302 includes a power supply 340, such as a battery, and a bus 342 to facilitate the communication of signals between components of the wireless communication device 302.

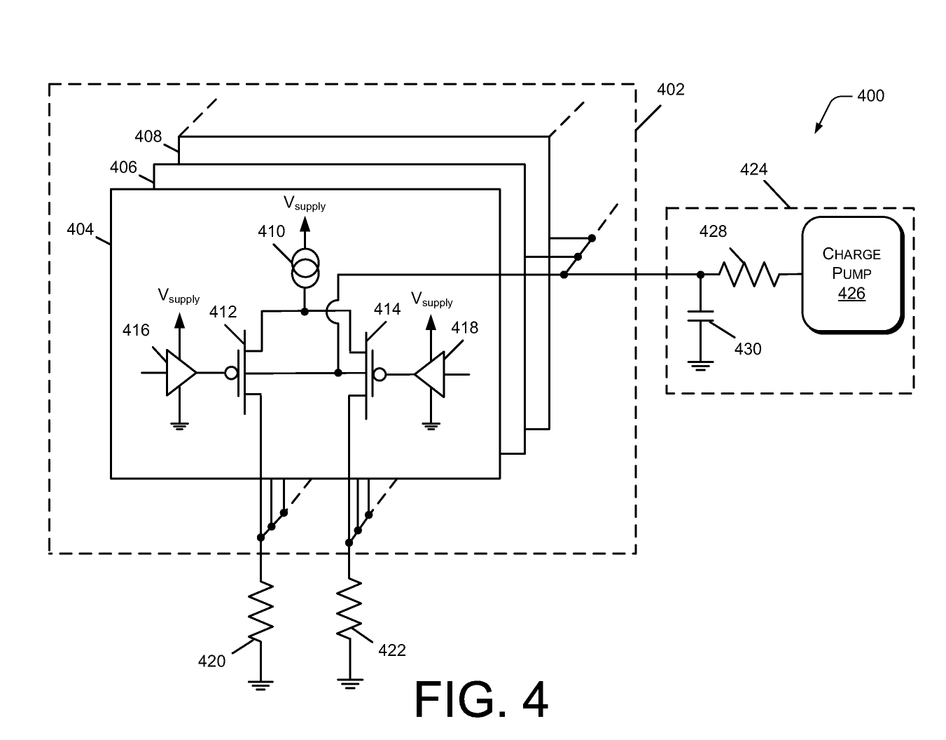

FIG. 4 shows a schematic circuit diagram of an architecture 400 including a digital to analog (D/A) converter circuit 402 connected to an on-chip voltage generator that is connected to a bulk region of PMOS transistors of transistor switches of the D/A converter circuit 402. The D/A converter circuit 402 includes one or more cells, such as the cells 404-408, that provide current utilized to produce an analog output voltage based on information of a digital input signal. Each of the cells 404-408 may correspond to a respective bit of the digital input signal. Accordingly, the current provided by each respective cell 404-408 is based on the value of the particular bit associated with the respective cell. Each of the cells 404-408 also receives a clock signal to synchronize the operation of the cells 404-408.

In some implementations, the arrangement of components of the first cell 404 shown in FIG. 4 is similar to the arrangement of components of the second cell 406 and the third cell 408. In a particular implementation, the first cell 404 of the D/A converter circuit 402 includes a current source 410. The current source 410 is connected to a positive supply voltage, V_{supply}. The first cell 404 also includes a first PMOS transistor 412 and a second PMOS transistor 414. A source of the first PMOS transistor 412 is connected to the current source 410 and a gate of the first PMOS transistor 412 is connected to first driver logic 416. The first driver logic 416 provides an activation voltage to the first PMOS transistor 412 to turn on the first PMOS transistor 412. That is, the first driver logic 416 provides a voltage that turns on the first PMOS transistor 412, such that the first PMOS transistor 412 is conducting current. In a particular example, the first driver logic 416 provides a voltage to turn on the first PMOS transistor 412 when a bit associated with the first cell 404 is a logical one. Further, when the bit associated with the first cell 404 is a logical zero, the first PMOS transistor 412 is turned off The first driver logic 416 is connected to ground and to the supply voltage, V_{supply}.

A source of the second PMOS transistor 414 is connected to the source of the first PMOS transistor 412 and is also connected to the current source 410. A gate of the second PMOS transistor 414 is connected to second driver logic 418. The second driver logic 418 provides an activation voltage to the second PMOS transistor 414 to turn on the second PMOS transistor 414. That is, the second driver logic 418 provides a voltage at the gate of the second PMOS transistor 414, such that the second PMOS transistor 414 is conducting current. In a particular example, the second driver logic 418 provides a voltage to turn on the second PMOS transistor 414 when a bit associated with the first cell 404 is a logical zero. Further, when the bit associated with the first cell 404 is a logical one, the second PMOS transistor 414 is turned off The second driver logic 418 is connected to ground and to the positive supply voltage V_{supply}.

A drain of the first PMOS transistor 412 is connected to a first impedance element 420, such as one or more resistors, one or more transistors, one or more capacitors, one or more inductors, or a combination thereof. Additionally, a drain of the second PMOS transistor 414 is connected to a second impedance element 422. The first impedance element 420 and the second impedance element 422 are also connected to ground.

In a particular implementation, the drain of the first PMOS transistor 412 is connected in parallel with the drains of the first PMOS transistors of the cells 406-408. The output currents of the first PMOS transistors of the cells 404-408 are summed and provided to the first impedance element 420. In some implementations, the sum of the output currents of the first PMOS transistors is passed through the first impedance element 420 to produce an analog output voltage based on information of the digital input signal. For example, one or more of the first PMOS transistors of the cells 404-408 may provide output currents to the first impedance device 420 and the sum of the currents provided may indicate a particular digital input code. To illustrate, a portion of a digital input signal including the code 011 may be represented by the first PMOS transistors of the second cell 406 and the third cell 408 providing output currents to the first impedance element 420, while the first PMOS transistor 412 provides little or no output current to the first impedance element 420.

Further, the drain of the second PMOS transistor 414 is connected in parallel with the drains of the second PMOS transistors of the cells 406-408. In some implementations, the output currents of the second PMOS transistors of the cells 404-408 may be utilized to represent the information associated with a digital input signal. For example, the output currents of the second PMOS transistors of the cells 404-408 may be summed and provided to the second impedance element 422. In other implementations, the output currents of the second PMOS transistors of the cells 404-408 may be discarded and not utilized to represent information of the digital input signal. The output currents of the first PMOS transistors and the second PMOS transistors of the cells 404-408 may be provided to another node of a communication device, rather than to the first impedance element 420 and the second impedance element 422, in order to provide some function of a communication device including the architecture 400.

The architecture 400 also includes a voltage generator 424. The voltage generator 424 is connected to the cells 404-408. For example, the voltage generator 424 is connected to a bulk region of the first PMOS transistor 412 and to a bulk region of the second PMOS transistor 414. The voltage generator 424 is also connected to the respective bulk regions of the first and second PMOS transistors of the cells 406 and 408. The voltage generator 424 may be connected to the positive supply voltage, V_{supply}, and provide a voltage to the bulk region of the first PMOS transistor 412 and a voltage to the bulk region of the second PMOS transistor 414 that is higher than the positive supply voltage. That is, the voltage generator 424 may provide a voltage to the bulk regions of the first and second PMOS transistors 412, 414 that has a higher positive value than the positive supply voltage. For example, when the positive supply voltage has a value of approximately 1.5 volts, the voltage generator 424 may provide a voltage of approximately 2.5 volts to the bulk regions of the first and second PMOS transistors 412, 414. Additionally, the voltage generator 424 includes a charge pump 426. In some implementations, the charge pump 426 may include a voltage doubler circuit.

The voltage generator 424 also includes an additional impedance element 428 and a capacitor 430. The additional impedance element 428 and the capacitor 430 may provide a filtering function to reduce ripple of the voltage provided by the voltage generator 424 to the D/A converter circuit 402. The additional impedance element 428 may include one or more resistors, one or more metal oxide semiconductor (MOS) transistors operating in a linear region, one or more capacitors, one or more inductors, or a combination thereof.

Additionally, the voltage generator 424 may be clocked at a particular frequency such that ripple of the bulk voltage provided by the voltage generator 424 does not interfere with an analog output voltage provided by the D/A converter circuit 402. In some implementations, the clock frequency of the voltage generator 424 may have a fixed relationship with a sampling clock frequency of the D/A converter circuit 402. For example, the clock frequency of the voltage generator 424 may be approximately the same as the clock frequency of the D/A converter circuit 402. In another example, the clock frequency of the voltage generator 424 may be approximately one-half of the clock frequency of the D/A converter circuit 402. In other implementations, the clock frequency of the voltage generator 424 may be independent of the clock frequency of the D/A converter circuit 402. Further, the clock frequency of the voltage generator 424 may be constant or vary over time.

In an illustrative implementation, the voltage generator 424 produces a voltage at the bulk terminals of the first PMOS transistor 412 and the second PMOS transistor 414, such that the threshold voltage of the first PMOS transistor 412 and the second PMOS transistor 414 is increased. In this way, the linear output voltage range produced at the first impedance element 420 and/or the second impedance element 422 is higher and less amplification is required with respect to other operations performed by circuitry including the architecture 400, such as a transmitter of a communication device. Thus, overall power consumption of the transmitter decreases.

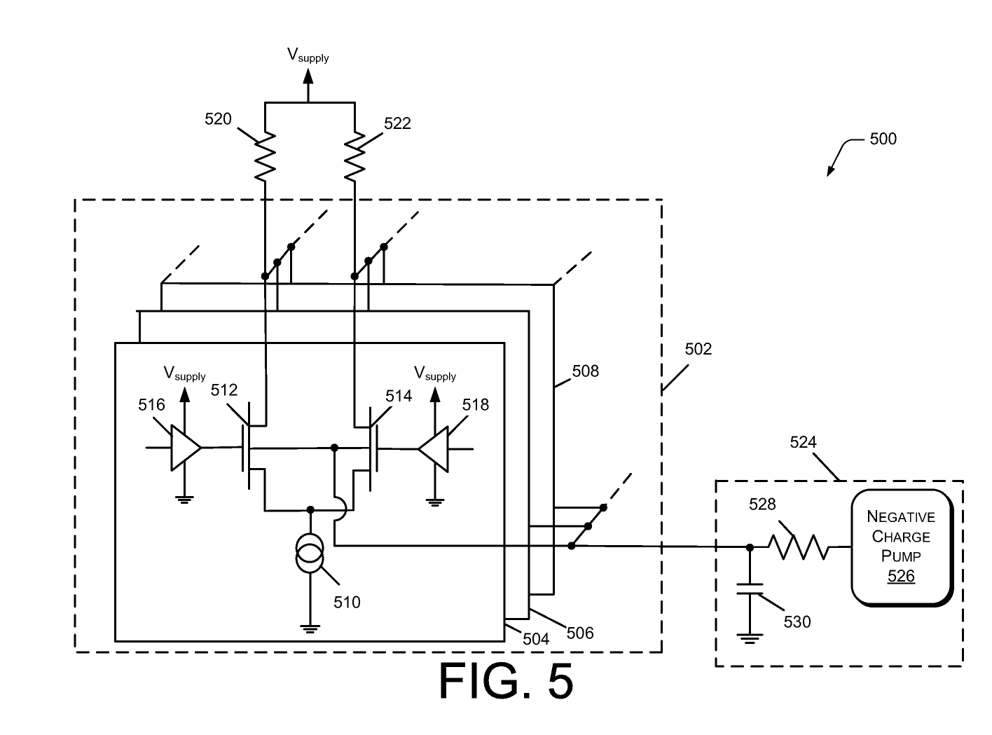

FIG. 5 shows a schematic circuit diagram of an architecture 500 including a digital to analog (D/A) converter circuit 502 connected to an on-chip voltage generator that is connected to a bulk region of NMOS transistors of transistor switches of the D/A converter circuit 502. The D/A converter circuit 502 includes one or more cells, such as the cells 504-508, that provide current utilized to produce an analog output voltage based on information of a digital input signal. Each of the cells 504-508 may correspond to a respective bit of the digital input signal. Accordingly, the current provided by each respective cell 504-508 is based on the value of the particular bit associated with the respective cell. Each of the cells 504-508 also receives a clock signal to synchronize the operation of the cells 504-508.

In some implementations, the arrangement of components of the first cell 504 shown in FIG. 5 is similar to the arrangement of components of the second cell 506 and the third cell 508. In a particular implementation, the first cell 504 of the D/A converter circuit 502 includes a current source 510. The current source 510 is connected to a negative supply voltage, such as ground. The first cell 504 also includes a first NMOS transistor 512 and a second NMOS transistor 514. The first NMOS transistor 512 and the second NMOS transistor 514 may have a bulk connection node that is separate from a connection to the substrate of the chip that includes the first NMOS transistor 512 and the second NMOS transistor 514. In some implementations, the first NMOS transistor 512 and the second NMOS transistor 514 are fabricated in a triple well complementary metal oxide semiconductor (CMOS) process.

A source of the first NMOS transistor 512 is connected to the current source 510 and a gate of the first NMOS transistor 512 is connected to first driver logic 516. The first driver logic 516 provides an activation voltage to the first NMOS transistor 512 to turn on the first NMOS transistor 512. That is, the first driver logic 516 provides a voltage at the gate of the first NMOS transistor 512 sufficiently above the threshold voltage of the first NMOS transistor 512, such that the first NMOS transistor 512 is conducting current. In a particular example, the first driver logic 516 provides a voltage to turn on the first NMOS transistor 512 when a bit associated with the first cell 504 is a logical one. Further, when the bit associated with the first cell 504 is a logical zero, the first NMOS transistor 512 is turned off The first driver logic 516 is connected to ground and to the supply voltage, V_{supply}.

A source of the second NMOS transistor 514 is connected to the source of the first NMOS transistor 512 and also connected to the current source 510. A gate of the second NMOS transistor 514 is connected to second driver logic 518. The second driver logic 518 provides an activation voltage to the second NMOS transistor 514 to turn on the second NMOS transistor 514. That is, the second driver logic 518 provides a voltage at the gate of the second NMOS transistor 514 that is sufficiently above the threshold voltage of the second NMOS transistor 514, such that the second NMOS transistor 514 is conducting current. In a particular example, the second driver logic 518 provides a voltage to turn on the second NMOS transistor 514 when a bit associated with the first cell 504 is a logical zero. Further, when the bit associated with the first cell 504 is a logical one, the second NMOS transistor 514 is turned off The second driver logic 518 is connected to ground and to the supply voltage, V_{supply}.

A drain of the first NMOS transistor 512 is connected to a first impedance element 520, such as one or more resistors, one or more transistors, one or more capacitors, one or more inductors, or a combination thereof. Additionally, a drain of the second NMOS transistor 514 is connected to a second impedance element 522. The first impedance element 520 and the second impedance element 522 are connected to the positive supply voltage, V_{supply}.

In a particular implementation, the drain of the first NMOS transistor 512 is connected in parallel with the drains of the first NMOS transistors of the cells 506-508. The output currents of the first NMOS transistors of the cells 504-508 are summed and provided to the first impedance element 520. In some implementations, the sum of the output currents of the first NMOS transistors is passed through the first impedance element 520 to produce an output voltage based on information of the digital input signal. For example, one or more of the first NMOS transistors of the cells 504-508 may provide output currents to the first impedance element 520 and the sum of the currents provided may indicate a particular digital input code.

Further, the drain of the second NMOS transistor 514 is connected in parallel with the drains of the second NMOS transistors of the cells 506-508. The output currents of the second NMOS transistors of the cells 504-508 are summed and provided to the second impedance element 522. In some implementations, the output currents of the second NMOS transistors of the cells 504-508 may be utilized to represent the information associated with a digital input signal. In other implementations, the output currents of the second NMOS transistors of the cells 504-508 may be discarded and not utilized to represent information of the digital input signal. The output currents of the first NMOS transistors and the second NMOS transistors may be provided to another node of a communication device, rather than to the first impedance element 520 and the second impedance element 522, in order to provide some function of a communication device including the architecture 500.

The architecture 500 also includes a voltage generator 524. The voltage generator 524 is connected to a bulk region of the first NMOS transistor 512 and to a bulk region of the second NMOS transistor 514. The voltage generator 524 is also connected to the first and second NMOS transistors of the cells 506 and 508. In some implementations, the voltage generator 524 is connected to the negative supply voltage and may provide a voltage to the bulk region of the first NMOS transistor 512 and a voltage to the bulk region of the second NMOS transistor 514 that is lower than the negative supply voltage. That is, the voltage generator 524 may provide a voltage to the bulk regions of the first and second NMOS transistors 512, 514 that has a more negative value than the negative supply voltage. For example, when the negative supply voltage is ground and has a value of approximately zero volts, the voltage generator 524 may provide a voltage that is less than zero to the bulk regions of the first and second NMOS transistors 512, 514. Additionally, the voltage generator 524 includes a negative charge pump 526.

The voltage generator 524 also includes an additional impedance element 528 and a capacitor 530. The additional impedance element 528 and the capacitor 530 may provide a filtering function to reduce ripple of the voltage provided by the voltage generator 524 to the D/A converter circuit 502. The impedance element 528 may include one or more resistors, one or more MOS transistors operating in a linear region, one or more capacitors, one or more inductors, or a combination thereof.

Additionally, the voltage generator 524 may be clocked at a particular frequency such that ripple of the bulk voltage provided by the voltage generator 524 does not interfere with an analog output voltage provided by the D/A converter circuit 502. In some implementations, the clock frequency of the voltage generator 524 may have a fixed relationship with a sampling clock frequency of the D/A converter circuit 502. For example, the clock frequency of the voltage generator 524 may be approximately the same as the clock frequency of the D/A converter circuit 502. In another example, the clock frequency of the voltage generator 524 may be approximately one-half of the clock frequency of the D/A converter circuit 502. In other implementations, the clock frequency of the voltage generator 524 may be independent of the clock frequency of the D/A converter circuit 502. Further, the clock frequency of the voltage generator 524 may be constant or vary over time.

In an illustrative implementation, the voltage generator 524 produces a voltage at the bulk terminals of the first NMOS transistor 512 and the second NMOS transistor 514, such that the threshold voltage of the first NMOS transistor 512 and the second NMOS transistor 514 is increased. In this way, the linear output voltage range that can be produced by the first impedance element 520 and/or the second impedance element 522 is higher and less amplification is required with respect to other operations performed by circuitry including the architecture 500.

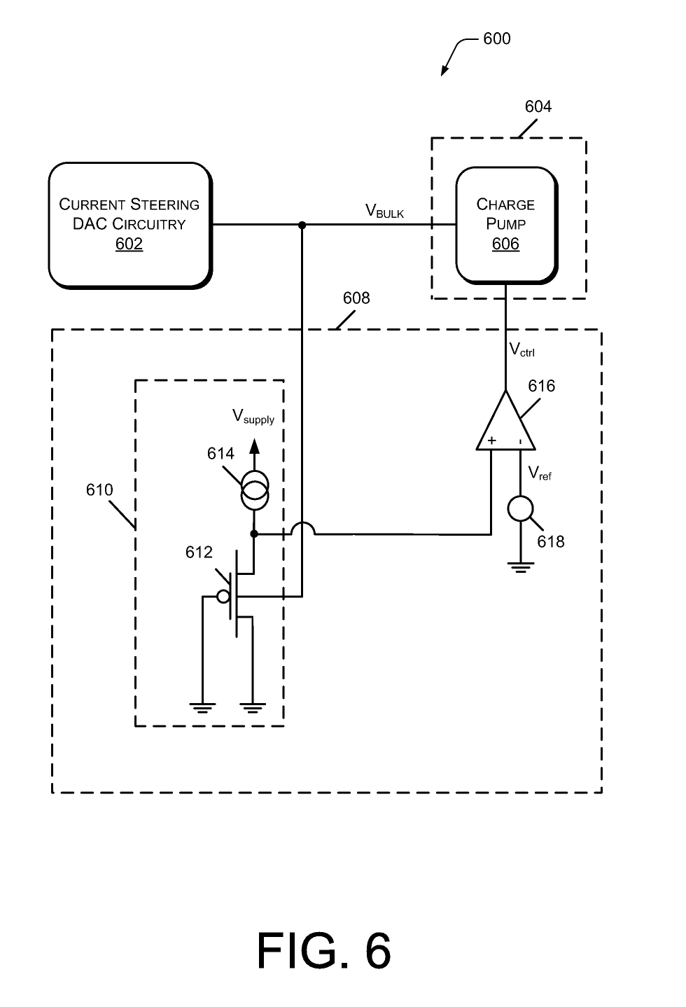

FIG. 6 shows a schematic circuit diagram of an architecture 600 to regulate a charge pump of a voltage generator connected to a bulk region of transistor switches of current steering digital to analog converter (DAC) circuitry 602. The current steering DAC circuitry 602 may include the digital to analog converter 202 of FIG. 2 and the digital to analog converter circuit 402 of FIG. 4. In another particular implementation, the current steering DAC circuitry 602 may include the digital to analog converter circuit 502 of FIG. 5. The current steering DAC circuitry 602 may produce an analog output voltage that represents information of a digital input signal.

The architecture 600 also includes a voltage generator 604. The voltage generator 604 is connected to the bulk regions of transistors of transistor switches of the current steering DAC circuitry 602. The voltage generator 604 produces a voltage, V_{Bulk}, at the bulk regions of the transistors of transistor switches of the current steering DAC circuitry 602, such that the threshold voltage of the transistors of the transistor switches of the current steering DAC circuitry 602 is increased. The increase of the threshold voltage of the switch transistors of the current steering DAC circuitry 602 increases the strength of the analog output voltage produced by the current steering DAC circuitry 602 and reduces the need for amplification of the analog output voltage in a communication device including the architecture 600.

The voltage V_{Bulk} may be produced by a charge pump 606. The charge pump 606 may be a positive charge pump when the transistors of the current steering DAC circuitry 602 are PMOS transistors and the charge pump 606 may be a negative charge pump when the transistors of the current steering DAC circuitry are NMOS transistors. The voltage generator 604 may also include a filtering arrangement connected to an output node of the charge pump 606, such as an impedance device-capacitor filter arrangement. In some implementations, the impedance device capacitor-filter arrangement is a resistor-capacitor (RC) filter arrangement. The filtering arrangement is not shown in FIG. 6 for the sake of simplicity.

In addition, the architecture 600 includes a regulation circuit 608. The regulation circuit 608 may regulate the voltage V_{bulk} provided to the current steering DAC circuitry 602 to provide better reproducibility of the voltage V_{bulk}. In a particular implementation, the regulation circuit 608 includes a replica cell 610. The replica cell 610 may include components similar to those of the cells of the current steering DAC circuitry 602. For example, the replica cell 610 includes a PMOS transistor 612 connected to a current source 614. The current source 614 is connected to a positive supply voltage V_{supply}. The PMOS transistor 612 and the current source 614 may be sized similarly to PMOS transistors and current sources of the cells of the current steering DAC circuitry 602. In some implementations, the current source 614 is a scaled version of the current sources of the current steering DAC circuitry 602. A gate and a drain of the PMOS transistor 612 are connected to ground. A bulk region of the PMOS transistor 612 is connected to the voltage generator 604. In an alternative implementation, the replica cell 610 includes an NMOS transistor rather than the PMOS transistor 612. In this alternative implementation, the replica cell 610 can be used with the D/A converter circuit 502 of FIG. 5 without a polarity inversion. However, when the replica cell 610 includes a PMOS transistor and the current steering DAC circuitry 602 includes the D/A converter circuit 502 of FIG. 5, a polarity inversion is needed.

The regulation circuit 608 also includes an operational amplifier 616. A first input of the operational amplifier 616 receives a reference voltage V_{ref} from a voltage source 618. A second input of the operational amplifier 616 receives a signal indicating a source voltage of the PMOS transistor 612. The operational amplifier 616 monitors and compares the reference voltage from the voltage source 618 and the source voltage of the PMOS transistor 612. In addition, the operational amplifier 616 amplifies a difference between V_{ref} and the source voltage of the PMOS transistor 612 and provides a corresponding control voltage, V_{ctrl}, to the voltage generator 604. The voltage generator 604 may modify the voltage V_{bulk} based on the control voltage received from the operational amplifier 616. For example, after receiving the control voltage V_{ctrl}, the voltage generator 604 may adjust V_{bulk} such that the source voltage of the PMOS transistor 612 is approximately equal to the reference voltage.

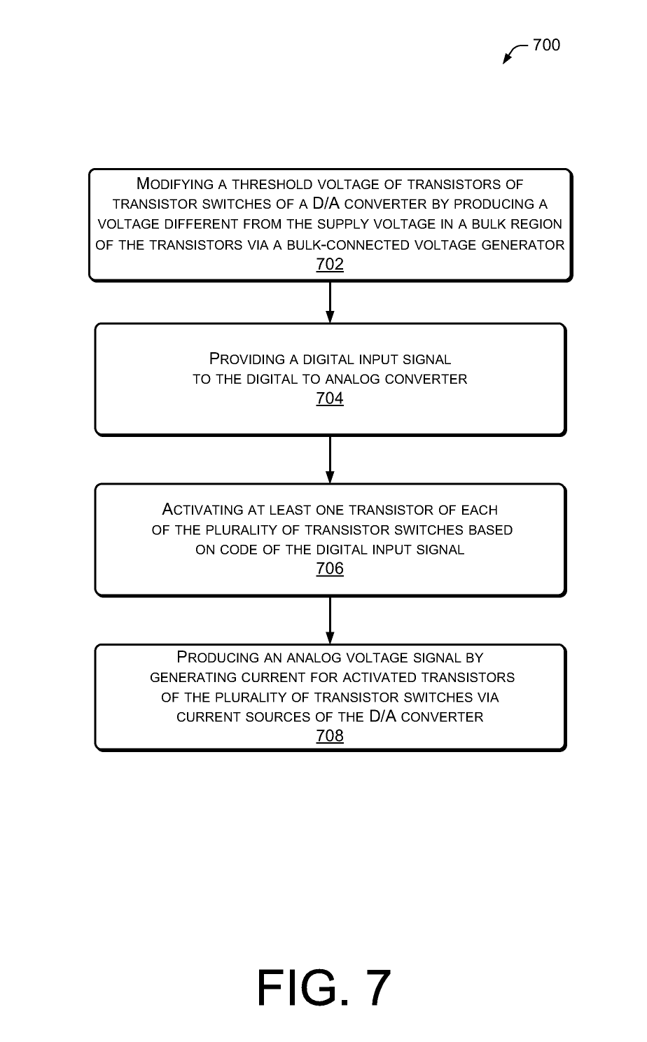

FIG. 7 shows a flowchart of a method 700 to modify a threshold voltage of transistors of transistor switches of a digital to analog converter via a bulk connected voltage generator. The method may be implemented utilizing the systems 100-600 shown in FIGS. 1-6, respectively. Specifics of exemplary methods are described below. However, it should be understood that certain acts need not be performed in the order described, and may be modified, and/or may be omitted entirely, depending on the circumstances.

At 702, the method 700 modifies a threshold voltage of transistors of a plurality of transistor switches of a digital to analog (D/A) converter by producing a voltage different from the supply voltage in a bulk region of the switch transistors via a voltage generator connected to the bulk region of the transistors. The voltage produced at the bulk region of each respective transistor of the transistor switches increases the threshold voltage of the respective transistors in order to decrease power consumption of a communication device including the D/A converter. The transistor switches of the D/A converter may be arranged in cells with each cell including a current source. The transistors of the transistor switches steer current from the current source to a particular output node. The transistors of the transistor switches may be NMOS transistors, PMOS transistors, or a combination thereof.

At 704, the D/A converter receives a digital input signal. The digital input signal may be received at the D/A converter from another component of a communication device including the D/A converter. The digital input signal may include a code of logical ones and zeroes utilized to express information.

At 706, at least one transistor of each of the plurality of transistor switches is activated based on code of the digital input signal. For example, each cell of the D/A converter may correspond to a particular bit of the digital input signal and a particular transistor of a respective pair of transistors of a transistor switch may be activated based on the value of the particular bit. To illustrate, one transistor of a particular transistor switch may be activated when the value of the particular bit is a logical one and another transistor of the particular transistor switch may be activated when the value of the particular bit is a logical zero. In some implementations, the activation voltage for the activated transistors is provided via driver logic connected to each respective activated transistor.

At 708, an analog voltage signal is produced by generating current for activated transistors of the plurality of transistor switches of the D/A converter via current sources of the D/A converter. The current sources of the D/A converter may be connected to a positive supply voltage or a negative supply voltage. In an illustrative implementation, when a particular transistor of a respective transistor switch is activated, current from a current source connected to the particular transistor may flow from the source of the transistor to the drain of the transistor and then to an output node connected to the particular transistor. In some implementations, the analog voltage signal is produced by summing output currents of transistor switches of the cells of the D/A converter and passing the sum of the currents through an impedance device connected to the D/A converter.

### CONCLUSION

Although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims.

1. A device comprising:
at least one current source connected to a supply voltage;
a voltage generator connected to a bulk region of a first transistor, the first transistor connected to the current source, and the voltage generator also connected to a bulk region of a second transistor, the second transistor connected to the current source and connected to the first transistor.

2. The device of claim 1, wherein a source of the first transistor is connected to a source of the second transistor.

3. The device of claim 1, wherein at least one of the first transistor or the second transistor is a positive channel metal oxide semiconductor (PMOS) transistor.

4. The device of claim 1, wherein at least one of the first transistor or the second transistor is a negative channel metal oxide semiconductor (NMOS) transistor.

5. The device of claim 3, wherein the supply voltage is a positive supply voltage.

6. The device of claim 5, wherein the voltage generator produces a voltage in the bulk region of the first transistor that is of a higher positive value than the positive supply voltage.

7. The device of claim 4, wherein the supply voltage is a negative supply voltage.

8. The device of claim 7, wherein the voltage generator produces a voltage in the bulk region of the first transistor that has a more negative value than the negative supply voltage.

9. The device of claim 4, wherein the first transistor and the second transistor are fabricated in a triple well CMOS process.

10. A digital to analog converter comprising:
a plurality of cells, wherein each cell includes a first transistor connected to a current source and a second transistor connected to the current source and connected to the first transistor; and
a voltage generator connected to a bulk region of the first transistor of each of the plurality of cells.

11. The digital to analog converter of claim 10, wherein the voltage generator is connected to a voltage regulation circuit.

12. The digital to analog converter of claim 11, wherein the voltage regulation circuit includes a replica cell, the replica cell including a current source and a transistor.

13. The digital to analog converter of claim 12, wherein the voltage regulation circuit includes an operational amplifier connected to the replica cell of the voltage regulation circuit and connected to the voltage generator, and wherein the operational amplifier provides a control voltage to a charge pump of the voltage generator.

14. The digital to analog converter of claim 13, wherein a first input of the operational amplifier receives a reference voltage and a second input of the operational amplifier receives a voltage signal from a source of the transistor of the replica cell.

15. The digital to analog converter of claim 14, wherein the control voltage is provided to the charge pump such that a source voltage of the transistor of the replica cell is approximately equal to the reference voltage.

16. A method comprising:
modifying a threshold voltage of transistors of a plurality of transistor switches of a digital to analog converter by producing a voltage different from a supply voltage in respective bulk regions of the transistors via a voltage generator connected to the respective bulk regions of the transistors.

17. The method of claim 16, further comprising:
providing a digital input signal to the digital to analog converter;
activating at least one transistor of each of the plurality of transistor switches based on code of the digital input signal;
producing an analog voltage signal by generating current for activated transistors of the plurality of transistor switches via current sources of the digital to analog converter, wherein the current sources are connected to the supply voltage.

18. The method of claim 16, wherein the voltage generator is clocked, and further comprising providing a clock signal to the clocked voltage generator, wherein a frequency of the clock signal is constant and has a fixed relation to a sampling clock frequency of the digital to analog converter.

19. The method of claim 16, wherein the voltage generator is clocked and further comprising providing a clock signal to the clocked voltage generator, wherein a frequency of the clock signal varies over time.

20. The method of claim 16, wherein the voltage generator is clocked and further comprising, providing a clock signal to the clocked voltage generator, wherein a frequency of the clock signal is independent of a sampling clock signal of the digital to analog converter.

21. The method of claim 16, wherein the voltage generator includes an impedance device-capacitor filter arrangement connected to an output node of a charge pump of the voltage generator.

22. The method of claim 21, wherein the impedance device of the filter arrangement is a metal oxide semiconductor (MOS) transistor operated in a linear region.

23. The method of claim 16, wherein the voltage generator includes a voltage doubler circuit.

24. The method of claim 16, wherein the voltage generator includes a DC/DC converter.
